(19) United States
(12) Patent Application Publication
(10) Pub. No.: US 2025/0326163 A1
(43) Pub. Date: Oct. 23, 2025

(54) MOLD RELEASE FILM AND METHOD FOR MANUFACTURING SEMICONDUCTOR PACKAGE

(71) Applicant: RESONAC CORPORATION, Tokyo (JP)

(72) Inventor: Koji NAKAMURA, Minato-ku, Tokyo (JP)

(73) Assignee: RESONAC CORPORATION, Tokyo (JP)

(21) Appl. No.: 18/861,765

(22) PCT Filed: Aug. 4, 2023
(86) PCT No.: PCT/JP2023/028608

§ 371 Date: Oct. 30, 2024

(30) Foreign Application Priority Data
Sep. 14, 2022 (JP) 2022-146410

(51) Int. Cl. B29C 33/68

(52) U.S. Cl. CPC B29C 33/68

(57) ABSTRACT

A mold release film including: a mold release layer; and a base material layer, in which an elongation rate at break of the mold release layer is 120% or more, and an average thickness of the mold release layer is 5 μm or more.

### TECHNICAL FIELD

The present disclosure relates to a mold release film and a method for manufacturing a semiconductor package.

### BACKGROUND ART

Semiconductor chips are usually sealed with a resin for the purpose of shielding from the external air and protection, and are mounted on substrates as molded products referred to as packages. Conventionally, the molded products have been molded as package molded products that each mount a single chip and that are mutually connected via runners as flow paths for a sealing resin. In this case, releasability of the molded products from a mold is obtained by the structure of the mold, addition of a release agent to a sealing resin, and the like.

Packages such as ball grid array (BGA) type, quad flat non-leaded (QFN) type, and wafer level chip size package (WL-CSP) type have increasingly been used due to, for example, demands for downsizing of packages and provision of multiple pins. In the QFN type, a resin-made mold release film is used in order to ensure the presence of the standoff and prevent the occurrence of burrs of a sealing material at terminals, and in the BGA type and the WL-CSP type, a resin-made mold release film is used in order to improve the releasability of a package from a mold (see, for example, Patent Literature 1). Molding methods using such a mold release film are referred to as “film-assisted molding”.

### CITATION LIST

### Patent Literature

Patent Literature 1; Japanese Patent Application Laid-Open (JP-A) No. 2002-158242

### SUMMARY OF INVENTION

### Technical Problem

Patent Literature 1 discloses a mold release film in which a layer responsible for releasability from a molded product is mainly made of an acrylic resin. From the viewpoint of releasability, it is preferable to employ a mold release layer made of an acrylic resin.

However, in recent years, a package structure becomes complicated, and precision of the package structure is also required. Therefore, the mold release film may be required to have characteristics other than releasability. For example, as the package structure becomes complicated, a part of the mold release layer is easily broken in a case in which the package is peeled off from the mold release film, and as a result, a phenomenon that a part of the broken mold release layer adheres to the package (hereinafter, also referred to as “mold release layer remaining”) easily occurs. It is desirable to reduce the occurrence of such mold release layer remaining.

The disclosure has been made in view of the above circumstances, and an object thereof is to provide a mold release film capable of reducing the occurrence of mold release layer remaining, and a method for manufacturing a semiconductor package using the mold release film.

### Solution to Problem

The disclosure includes the following aspects.
<1> A mold release film including: a mold release layer; and a base material layer, in which an elongation rate at break of the mold release layer is 120% or more, and an average thickness of the mold release layer is 5 μm or more.
<2> The mold release film according to <1>, in which the mold release layer contains a urethane resin.
<3> A mold release film including: a mold release layer; and a base material layer, in which the mold release layer contains a urethane resin, and the urethane resin includes a constituent unit 1 having an alkylene oxide skeleton.
<4> The mold release film according to any one of <1> to <3>, in which the base material layer is a polyester film.
<5> The mold release film according to <2>, in which the urethane resin includes a constituent unit 1 having an alkylene oxide skeleton.
<6> The mold release film according to <3> or <5>, in which the constituent unit 1 includes at least one of a constituent unit 2 having an ethylene oxide skeleton or a constituent unit 3 having a propylene oxide skeleton.
<7> The mold release film according to any one of <3>, <5>, and <6>, in which the urethane resin further includes a constituent unit 4 having each urethane bond at both ends of a divalent linking group, and a total content ratio of the constituent unit 2 and the constituent unit 3 is 50 mol % or more with respect to a total of the constituent unit 1 and the constituent unit 4.
<8> The mold release film according to any one of <3>, <5>, <6>, and <7>, in which the constituent unit 1 includes the constituent unit 2 and the constituent unit 3, and a ratio of the constituent unit 2 and the constituent unit 3, i.e., the constituent unit 2:the constituent unit 3 is from 10:90 to 60:40.
<9> The mold release film according to any one of <2>, <3>, and <5> to <8>, in which the urethane resin includes a constituent unit 4 having each urethane bond at both ends of a divalent linking group, and the divalent linking group is a hexamethylene group, a 2,2,4-trimethylhexamethylene group, a 2,4,4-trimethylhexamethylene group, a pentamethylene group, or a tetramethylene group.
<10> The mold release film according to any one of <1> to <9>, in which the mold release film is used in transfer molding or compression molding.
<11> A method for manufacturing a semiconductor package, including performing transfer molding or compression molding using the mold release film according to any one of <1> to <10>.

### Advantageous Effects of Invention

According to the disclosure, there are provided a mold release film capable of reducing the occurrence of mold release layer remaining, and a method for manufacturing a semiconductor package using the mold release film.

### BRIEF DESCRIPTION OF DRAWINGS

FIG. 1 is a view illustrating a test piece used for measuring an elongation rate at break (%) of a mold release layer.

### DESCRIPTION OF EMBODIMENTS

Hereinafter, embodiments of the present invention will be described in detail. However, the invention is not limited to the following embodiments.

In the disclosure, a numerical range that has been indicated by use of “to” includes the numerical values which are described before and after “to”, as a minimum value and a maximum value, respectively.

In a numerical range described in a stepwise manner in the disclosure, an upper limit value or a lower limit value described in one numerical range may be replaced with an upper limit value or a lower limit value described in another numerical range described in a stepwise manner. In a numerical range described in the disclosure, an upper limit value or a lower limit value of the numerical range may be replaced with a value shown in Examples.

In the disclosure, each component may contain a plurality of corresponding substances. In a case in which a plurality of substances corresponding to each component are present in the composition, the content ratio or content of each component means the total content ratio or content of the plurality of substances present in the composition unless otherwise specified.

In the disclosure, the term “layer” includes, in a case in which a region in which the layer is present is observed, not only a case in which the layer is formed over an entire area of the region, but also a case in which the layer is formed only in a part of the region.

In the disclosure, the average thickness (also referred to as the average value of the thicknesses) of a layer or a film refers to a value that is obtained as an arithmetic average value of thicknesses measured at five points on the layer or the film to be measured.

The thickness of the layer or the film can be measured using a micrometer or the like. In the disclosure, in a case in which the thickness of the layer or the film can be directly measured, the measurement is performed using a micrometer. In a case in which the thickness of one layer or the total thickness of a plurality of layers is to be measured, the measurement may be performed by observing a cross-section of the film using an electron microscope.

Hereinafter, as for a mold release film of the disclosure, mold release films of a first embodiment and a second embodiment will be described. The mold release film of the disclosure is not limited to the following first embodiment and second embodiment. Configurations that can be taken in the first embodiment and the second embodiment may be appropriately combined.

### First Embodiment

### <Mold Release Film>

The mold release film in the first embodiment of the disclosure includes a mold release layer and a base material layer, in which an elongation rate at break of the mold release layer is 120% or more, and an average thickness of the mold release layer is 5 μm or more. The elongation rate at break of the mold release layer is 120% or more.

The mold release film of the first embodiment can reduce the occurrence of mold release layer remaining by adopting the above-described configuration. The reason for this is not clear, but is presumed as follows.

In the mold release film of the disclosure, in a case in which the elongation rate at break of the mold release layer is 120% or more, and the average thickness of the mold release layer is 5 μm or more, stretchability is excellent, and a part of the mold release layer is less likely to be broken in a case in which a semiconductor package is peeled off. As a result, a part of the mold release layer is less likely to adhere to the semiconductor package, and the occurrence of mold release layer remaining can be reduced.

The mold release film of the disclosure is preferably used for semiconductor molding. More specifically, the mold release film of the disclosure is preferably used in a case in which a semiconductor package is manufactured by a sealing material in a state in which the base material layer is brought into contact with a mold used in resin molding of a semiconductor package and the mold release layer is located on a semiconductor chip side to be molded.

### [Mold Release Layer]

The mold release film of the disclosure includes a mold release layer. The configuration of the mold release layer is not particularly limited as long as the elongation rate at break is 120% or more and the average thickness is 5 μm or more.

### (Elongation Rate at Break of Mold Release Layer)

The elongation rate at break of the mold release layer is 120% or more, preferably 150% or more, and more preferably 180% or more. The elongation rate at break of the mold release layer can be adjusted by, for example, the composition of a resin component constituting the mold release layer, the blending amount of a crosslinking agent described later, or the like. The upper limit value of the elongation rate at break of the mold release layer is not particularly limited, and may be, for example, 800% or less, may be 500% or less, and may be 300% or less.

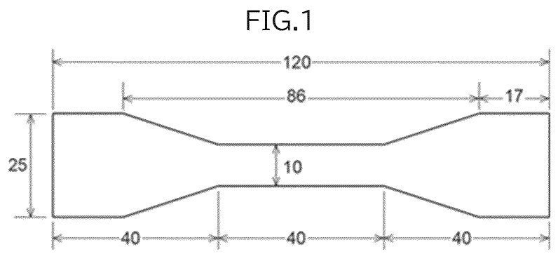

The elongation rate at break (%) of the mold release layer is measured as follows. First, a test piece having a shape as illustrated in FIG. 1 is prepared using the mold release film. The unit of the numerical value in FIG. 1 is mm. A tensile test is performed by grasping both ends of the test piece with a tester. The measurement is performed under the condition of 170° C., and the tensile rate is set to 200 mm/min. The elongation rate at break of the mold release layer is calculated by the following formula from a gage length A (length of a portion where the width of the test piece illustrated in FIG. 1 is 10 mm: 40 mm) of the sample before the test and a gage length B in a case in which the mold release layer is broken.

$$[ Mathematical Formula 1 ]$$

$$Elongation rate at break ( \% ) of mold release layer = \frac{B - A}{A} \times 100$$

For the measurement of the elongation rate at break of the mold release layer of the mold release film, for example, “TENSILON Tensile Tester RTA-100 type” manufactured by ORIENTEC CO., LTD., “TENSILON Universal Tester RTG-1210” manufactured by A & D Company, Limited, or a tester similar thereto and having a knob may be used.

### (Average Thickness of Mold Release Layer)

The average thickness of the mold release layer is 5 μm or more, may be from 5 μm to 40 μm, and may be from 5 μm to 30 μm.

The mold release layer may contain a resin component. The resin component of the mold release layer is not particularly limited, and examples thereof include a urethane resin, an acrylic resin, and a silicone resin. In particular, from the viewpoint of an excellent elongation rate at break of the mold release layer, the mold release layer preferably contains a urethane resin.

In the disclosure, the urethane resin is preferably a resin component having a urethane bond in the main chain of the resin, and more preferably a resin component having a plurality of constituent units each including a urethane bond in the main chain of the resin.

The mold release layer may contain only one resin component, and may contain two or more resin components. For example, the mold release layer may be a layer containing only a urethane resin as a resin component, and may be a layer containing two kinds of a urethane resin and an acrylic resin or two kinds of a urethane resin and a silicone resin.

The mold release layer may contain a crosslinked urethane resin as the urethane resin, and may contain a crosslinked acrylic resin as the acrylic resin. From the viewpoint of a balance between reduction of the occurrence of mold release layer remaining and releasability, the mold release layer preferably contains a crosslinked urethane resin as the urethane resin.

In the disclosure, the crosslinked urethane resin means a resin obtained by crosslinking a urethane resin with a crosslinking agent, and the crosslinked acrylic resin means a resin obtained by crosslinking an acrylic resin with a crosslinking agent.

The urethane resin may be a resin obtained by reacting a polyol compound having a plurality of hydroxy groups with a polyisocyanate compound having a plurality of isocyanate groups. The urethane resin may contain a compound having a plurality of urethane bonds in the main chain, and may contain a compound having a plurality of urethane bonds in the main chain and having a hydroxy group on at least one of both ends of the main chain.

The urethane resin preferably includes a constituent unit 1 having an alkylene oxide skeleton. The urethane resin may include a plurality of constituent units 1. The urethane resin may include only one constituent unit 1, and may include two or more kinds of constituent units 1. In a case in which the urethane resin includes a plurality of two or more kinds of constituents unit 1, the urethane resin may be a block polymer of the constituent units 1, and may be a random polymer of the constituent units 1.

The constituent unit 1 having an alkylene oxide skeleton preferably includes at least one of a constituent unit 2 having an ethylene oxide skeleton or a constituent unit 3 having a propylene oxide skeleton, and preferably contains both the constituent unit 2 and the constituent unit 3.

A total content ratio of the constituent unit 2 and the constituent unit 3 may be 50 mol % or more, may be from 80 mol % to 100 mol %, and may be from 90 mol % to 100 mol %, with respect to the total amount of the constituent unit 1.

In the disclosure, the content ratio of each constituent unit can be calculated, for example, from measurement of ¹H NMR.

The constituent unit 1 includes the constituent unit 2 and the constituent unit 3, and a ratio of the constituent unit 2 and the constituent unit 3, i.e., the constituent unit 2: the constituent unit 3 may be from 10:90 to 60:40, may be from 10:90 to 55:45, and may be from 15:85 to 50:50.

The urethane resin preferably further includes a constituent unit 4 having each urethane bond at both ends of a divalent linking group (that is, *-urethane bond-divalent linking group-urethane bond-*, * represent bonding positions). The urethane resin more preferably includes the constituent unit 1 having an alkylene oxide skeleton together with the constituent unit 4, and still more preferably includes both the constituent unit 2 having an ethylene oxide skeleton and the constituent unit 3 having the propylene oxide skeleton.

The urethane resin further contains the constituent unit 4, and the total content ratio of the constituent unit 2 and the constituent unit 3 may be 50 mol % or more, may be from 80 mol % to 99.5 mol %, may be from 90 mol % to 99 mol %, and may be from 95 mol % to 99 mol %, with respect to the total of the constituent unit 1 and the constituent unit 4.

The divalent linking group contained in the constituent unit 4 is preferably a substituted or unsubstituted hydrocarbon group, and more preferably a linear or branched hydrocarbon group not containing a ring structure. The number of carbon atoms in the divalent linking group may be from 2 to 20, may be from 3 to 15, and may be from 4 to 10.

Examples of the divalent linking group contained in the constituent unit 4 include a hexamethylene group, a 2,2,4-trimethylhexamethylene group, a 2,4,4-trimethylhexamethylene group, a pentamethylene group, and a tetramethylene group.

The constituent unit 4 may be a constituent unit derived from a diisocyanate compound, and may be a constituent unit derived from hexamethylene diisocyanate, 2,2,4-trimethylhexamethylene diisocyanate, 2,4,4-trimethylhexamethylene diisocyanate, pentamethylene diisocyanate, or tetramethylene diisocyanate.

A content ratio of the constituent unit 4 may be 50 mol % or less, may be from 0.5 mol % to 20 mol %, may be from 1 mol % to 10 mol %, and may be from 1 mol % to 5 mol %, with respect to the total constituent units included in the urethane resin.

The acrylic resin is preferably an acrylic copolymer obtained by copolymerizing a monomer having a low glass transition temperature (Tg), such as butyl acrylate, ethyl acrylate, or 2-ethylhexyl acrylate, as a main monomer with a functional group monomer such as acrylic acid, methacrylic acid, hydroxyethyl methacrylate, hydroxyethyl acrylate, 4-hydroxybutyl acrylate, acrylamide, or acrylonitrile.

Whether the resin component contains a urethane resin, an acrylic resin, or the like may be confirmed by IR measurement. NMR measurement, or the like.

Examples of the crosslinking agent used for producing the crosslinked urethane resin or the crosslinked acrylic resin include known crosslinking agents such as an isocyanate compound, a melamine compound, and an epoxy compound, and among them, an isocyanate compound is preferable.

The crosslinked urethane resin or the crosslinked acrylic resin produced by using the crosslinking agent as described above has a gently spreading network structure. Therefore, in a case in which the resin described above is used as the resin component of the mold release layer, the stretchability of the mold release layer is improved, and inhibition of the stretchability of the base material layer is suppressed. As a result, there is a tendency that followability of the mold release film to a mold is improved.

From the viewpoint of a balance between the elongation rate at break of the mold release laver and the followability of the mold release film to a mold, the crosslinking agent is preferably a bifunctional to tetrafunctional polyfunctional crosslinking agent, and more preferably a bifunctional or trifunctional polyfunctional crosslinking agent. The polyfunctional crosslinking agent described above is preferably a bifunctional or trifunctional isocyanate compound. Examples of the bifunctional or trifunctional isocyanate compound include 2,6-toluene diisocyanate, 2,4-toluene diisocyanate, 4,4′-diphenylmethane diisocyanate, and 1,6-hexane diisocyanate.

The crosslinked urethane resin preferably has a urethane bond in the main chain and a urethane bond in the side chain that crosslinks the main chains, and more preferably has a plurality of urethane bonds in the main chain and a urethane bond in the side chain that crosslinks the main chains.

From the viewpoint of an excellent elongation rate at break of the mold release layer and excellent followability of the mold release film to a mold, the resin component preferably contains a crosslinked urethane resin. A content ratio of the crosslinked urethane resin with respect to the entire resin component may be from 50% by mass to 100% by mass, may be from 70% by mass to 100% by mass, and may be from 90% by mass to 100% by mass.

An amount of the crosslinking agent used in the production of the crosslinked urethane resin or the crosslinked acrylic resin (preferably the production of the crosslinked urethane resin) may be from 10 parts by mass to 50 parts by mass, may be from 15 parts by mass to 40 parts by mass, and from the viewpoint of peelability from the semiconductor package, the amount may be from 20 parts by mass to 30 parts by mass, with respect to 100 parts by mass of the resin to be crosslinked.

In a case in which the mold release layer contains a resin component, a content ratio of the resin component may be from 50% by mass to 100% by mass, may be from 80% by mass to 100% by mass, and may be from 90% by mass to 100% by mass, with respect to the entire mold release layer.

### (Another Component)

The mold release layer may further contain another component, which are other than the resin component, such as a solvent, an anchoring improver, a crosslinking accelerator, an antistatic agent, a colorant, or inorganic particles, if necessary, as long as the effect of the invention is exhibited.

### [Base Material Layer]

The mold release film of the disclosure includes a base material layer. The base material layer is not particularly limited, and can be appropriately selected from resin-containing base material layers used in the technical field. From the viewpoint of improving the followability to the shape of a mold, it is preferable to use a resin-containing base material layer excellent in stretchability.

Considering that the molding of the sealing material is performed at a high temperature (from about 100° C. to 200° C.), the base material layer desirably has heat resistance equal to or higher than this temperature. From the viewpoint of suppressing the occurrence of wrinkles of the sealing resin, breakage of the mold release film, and the like in a case in which the mold release film is attached to a mold and the resin during molding flows, it is preferable to select the material of the base material layer in consideration of the elastic modulus, elongation, and the like at a high temperature.

From the viewpoint of heat resistance and elastic modulus at a high temperature, the material of the base material layer is preferably a polyester resin. Examples of the polyester resin include a polyethylene terephthalate resin, a polyethylene naphthalate resin, a polybutylene terephthalate resin, and copolymers and modified resins thereof.

The base material layer is preferably obtained by molding a polyester resin into a sheet shape, the base material layer is more preferably a polyester film, and from the viewpoint of followability to a mold, the base material layer is preferably a biaxially stretched polyester film.

An average thickness of the base material layer is not particularly limited, and is preferably from 5 μm to 300 μm, more preferably from 10 μm to 200 μm, and still more preferably from 20 μm to 100 μm. In a case in which the average thickness is 5 μm or more, there is a tendency that handleability is excellent and wrinkles are hardly generated. In a case in which the average thickness is 300 μm or less, since the followability to a mold during molding is excellent, there is a tendency that the occurrence of wrinkles and the like of the molded semiconductor package is suppressed.

### [Others]

The base material layer is a layer located on a mold surface side, and depending on the material to be used, a larger peel strength may be required to peel the mold release film from the mold. In the case of using a material that is hardly peeled off from the mold for the base material layer as described above, it is preferable that the mold release film is easily peeled off from the mold. For example, an opposite surface of the base material layer in contact with the mold release layer, that is, a surface of the base material layer on the mold side may be subjected to surface processing such as satin processing in order to improve releasability from the mold, or another mold release layer (second mold release layer) may be newly provided. The material of the second mold release layer is not particularly limited as long as it satisfies heat resistance, releasability from a mold, and the like, and the same material as that of the mold release layer may be used. An average thickness of the second mold release layer is not particularly limited, and may be from 0.1 μm to 100 μm.

If necessary, a layer such as an anchoring improving layer, an antistatic layer, or a colored layer of the mold release layer or the second mold release layer may be provided, for example, between the mold release layer and the base material layer or between the base material layer and the second mold release layer. Examples of a preferable layer configuration include a three-layer structure in which a base material layer, an antistatic layer, and a mold release layer are provided in this order. The antistatic layer may contain an antistatic polymer such as a quaternary ammonium salt-containing polymer or a polythiophene-based polymer.

A total thickness of the mold release film is preferably 350 μm or less and more preferably 200 μm or less, from the viewpoint of followability to a mold. The total thickness of the mold release film is preferably 10 μm or more and more preferably 20 μm or more, from the viewpoint of handleability.

### Second Embodiment

### <Mold Release Film>

The mold release film in the second embodiment of the disclosure includes a mold release layer and a base material layer, in which the mold release layer contains a urethane resin, and the urethane resin includes a constituent unit 1 having an alkylene oxide skeleton.

The mold release film of the second embodiment can reduce the occurrence of mold release layer remaining by adopting the above-described configuration. The reason for this is not clear, but is presumed as follows.

In the mold release film of the disclosure, the mold release layer contains a urethane resin, and the urethane resin includes a constituent unit 1 having an alkylene oxide skeleton, so that stretchability is excellent, and a part of the mold release layer is less likely to be broken in a case in which a semiconductor package is peeled of. As a result, a part of the mold release layer is less likely to adhere to the semiconductor package, and the occurrence of mold release layer remaining can be reduced.

### [Method of Producing Mold Release Film]

The mold release film of the disclosure can be produced by a known method. For example, the mold release film of the disclosure can be produced by applying a composition for forming a mold release layer to one surface of a base material layer and drying the composition. The composition for forming a mold release layer may contain a resin component and another component added if desired. For example, the composition for forming a mold release layer may contain a resin component such as a urethane resin, a crosslinking agent, and another component if necessary.

### Preparation of Composition for Forming Mold Release Layer

A method of preparing a composition for forming a mold release layer is not particularly limited, examples thereof include a method in which a resin component or the like is dispersed and dissolved in a solvent, and the composition for forming a mold release layer can be prepared using a known composition preparation method.

The solvent used for preparing the composition for forming a mold release layer is not particularly limited, and is preferably an organic solvent capable of dissolving or dispersing a resin component or the like. Examples of the organic solvent include toluene, methyl ethyl ketone, and ethyl acetate.

### [Application and Drying]

The method of applying the composition for forming a mold release layer to one surface of the base material layer is not particularly limited, and a known coating method such as a roll coating method, a bar coating method, or a kiss coating method can be used. In a case in which the composition for forming a mold release layer is applied, it is preferable to apply the composition for forming a mold release layer so that the average thickness of the composition layer (mold release layer) after drying is 5 μm or more.

The method of drying the applied composition for forming a mold release layer is not particularly limited, and a known drying method can be used. For example, a method of performing drying at from 50° C. to 150° C. for from 0.1 minutes to 60 minutes may be employed.

In a case in which the composition for forming a mold release layer contains a urethane resin and a crosslinking agent, a mold release layer containing a crosslinked urethane resin may be formed by allowing a crosslinking reaction between the urethane resin and the crosslinking agent to proceed by a drying treatment.

### [Use Application]

The mold release film of the disclosure can be used in molding of a semiconductor package, and can be suitably used in transfer molding or compression molding.

### <Method for Manufacturing Semiconductor Package>

A method for manufacturing a semiconductor package of the disclosure includes performing transfer molding or compression molding using the above-described mold release film of the disclosure.

In the transfer molding, for example, a semiconductor chip is disposed in a mold of a transfer molding apparatus, a mold release film is disposed in the other mold, and the mold release film is caused to follow the shape of the mold by vacuum suction or the like. Next, the mold is closed, a molten thermosetting sealing material (for example, an epoxy resin) is injected into the heated mold by a transfer method, and the sealing material is cured to mold a semiconductor package. Thereafter, the mold is opened, and the molded semiconductor package is taken out.

In the compression molding, for example, a mold release film is disposed in a mold of a compression molding apparatus, and the mold release film is caused to follow the shape of the mold by vacuum suction or the like. Next, a thermosetting sealing material (for example, an epoxy resin) of a semiconductor package is placed in the mold, a semiconductor chip is disposed thereon, and the mold is compressed while being heated to cure the sealing material, thereby molding a semiconductor package. Thereafter, the mold is opened, and the molded semiconductor package is taken out.

In the method for manufacturing a semiconductor package of the disclosure, the above-described mold release film of the disclosure is used. As a result, in a case in which the semiconductor package after molding is peeled off from the mold release film and the semiconductor package is taken out, a part of the mold release layer is less likely to be broken. As a result, a part of the mold release layer is less likely to adhere to the semiconductor package, and the occurrence of mold release layer remaining can be reduced.

### EXAMPLES

Hereinafter, the invention will be described specifically with reference to Examples. However, the invention is not limited to these Examples.

### Synthesis of Acrylic Resin

An acrylic resin was synthesized by copolymerization using the monomers shown in the following Table 1 in the blending amount (parts by mass) shown in Table 1 by solution polymerization. In Table 1, BA is butyl acrylate, and 4-HBA is 4-hydroxybutyl acrylate.

The number average molecular weight Mn and the weight average molecular weight Mw of the obtained acrylic resin were measured by gel permeation chromatography (GPC) in terms of standard polystyrene.

Mn and Mw of the obtained acrylic resin are shown in Table 1.

TABLE 1

| | Acrylic resin |
|---|---|
| BA | 92 |
| 4-HBA | 8 |
| Mn | 144,000 |
| Mw | 854,000 |

### Example 1

A composition for forming a mold release layer was prepared by mixing 100 parts by mass of a urethane resin (LION SPECIALTY CHEMICALS CO., LTD.: US-1353H) with a toluene solution having a solid content of 15% by mass prepared by adding 20 parts by mass of Coronate L (TOSOH CORPORATION, trade name) as a crosslinking agent to toluene. A biaxially stretched polyethylene terephthalate film (UNITIKA LTD.: S-38) subjected to a corona treatment and having an average thickness of 38 μm was used as a base material layer. Thereafter, the composition for forming a mold release layer was applied to one surface of the base material layer using a roll coater so that the average thickness after drying was 5 μm, and dried to form a mold release layer, thereby obtaining a mold release film.

### Example 2

A mold release film was prepared in the same manner as in Example 1, except that the average thickness of the mold release layer after drying was set to 10 μm.

### Example 3

A mold release film was prepared in the same manner as in Example 1, except that the average thickness of the mold release layer after drying was set to 25 μm.

### Example 4

A mold release film was prepared in the same manner as in Example 2, except that the crosslinking agent was set to 40 parts by mass with respect to 100 parts by mass of the urethane resin.

### Example 5

A mold release film was prepared in the same manner as in Example 4, except that the average thickness of the mold release layer after drying was set to 15 μm.

### Comparative Example 1

A mold release film was prepared in the same manner as in Example 3, except that 100 parts by mass of the acrylic resin synthesized in place of 100 parts by mass of the urethane resin was used, and the crosslinking agent was set to 10 parts by mass.

### Comparative Example 2

A mold release film was prepared in the same manner as in Example 2, except that 100 parts by mass of the acrylic resin synthesized in place of 100 parts by mass of the urethane resin was used.

### Comparative Example 3

A mold release film was prepared in the same manner as in Comparative Example 2, except that the average thickness of the mold release layer after drying was set to 20 μm.

### Comparative Example 4

A mold release film was prepared in the same manner as in Comparative Example 2, except that the average thickness of the mold release layer after drying was set to 25 μm.

### (Elongation Rate at Break of Mold Release Layer)

The elongation rate at break of the mold release layer at 170° C. was measured by the above-described method. For the measurement, “TENSILON Tensile Tester RTA-100 type” manufactured by ORIENTEC CO., LTD. was used. The results are shown in Table 2.

(Evaluation of Releasability with Respect to EMC)

The releasability with respect to an epoxy molding compound (EMC) as a sealing material was evaluated as follows.

A heating and pressurizing treatment was performed in a state in which the mold release layer of the mold release film was in contact with a sealing material (Showa Denko Materials Co., Ltd.: trade name “CEL-9750ZHF10”). The temperature was set to 175° C., the pressure was set to 6 KPa, and the treatment time was set to 4 minutes.

As an index of the releasability of the mold release film from the sealing material after the heating and pressurizing treatment, a peel strength was measured in a case in which a peel test was performed at a peeling angle of 180° and a peeling rate of 1000 mm/min. From the measured numerical values of peel strength, the releasability was evaluated according to the following criteria. The results are shown in Table 2. In the case of Evaluation A or Evaluation B, the releasability is favorable.

### Evaluation Criteria

A: less than 150 mN/50 mm
B: 150 mN/50 mm or more but less than 250 mN/50 mm
C: 250 mN/50 mm or more

### (Presence or Absence of Mold Release Layer Remaining)

An SUS plate (width: 5 mm, thickness: 0.6 mm) was brought into contact with the base material layer side of the mold release film. An SUS plate (width: 50 mm, thickness: 0.6 mm) was disposed on the mold release layer side, and a heating and pressurizing treatment at 170° C. and 32 MPa was performed for 5 minutes.

After the heating and pressurizing treatment, the mold release film was peeled off from the SUS plate on the mold release layer side. Thereafter, the presence or absence of mold release layer remaining on the SUS plate disposed on the mold release layer side was observed by visual inspection and “Digital Microscope VHX-7000” (20 times) manufactured by KEYENCE CORPORATION, and evaluated according to the following criteria. The results are shown in Table 2.
A: No mold release layer remaining was observed in either visual inspection or microscopic observation.
B: Mold release layer remaining was observed by at least one of visual inspection or microscopic observation.

TABLE 2

| | | Example | Example | Example | Example | Example | Comparative | Comparative | Comparative | Comparative |
|---|---|---|---|---|---|---|---|---|---|---|
| | | 1 | 2 | 3 | 4 | 5 | Example 1 | Example 2 | Example 3 | Example 4 |
| Mold | Urethane resin | 100 | 100 | 100 | 100 | 100 | 0 | 0 | 0 | 0 |
| release | (parts by mass) | | | | | | | | | |
| layer | Acrylic resin | 0 | 0 | 0 | 0 | 0 | 100 | 100 | 100 | 100 |
| main | (parts by mass) | | | | | | | | | |
| agent | | | | | | | | | | |

| | | | | | | | | | |
|---|---|---|---|---|---|---|---|---|---|
| Crosslinking agent | 20 | 20 | 20 | 40 | 40 | 10 | 20 | 20 | 20 |
| (parts by mass) | | | | | | | | | |
| Average thickness of | 5 | 10 | 25 | 10 | 15 | 25 | 10 | 20 | 25 |
| mold release layer | | | | | | | | | |
| (μm) | | | | | | | | | |
| Elongation rate at break | 180≤ | 180≤ | 165 | 180≤ | 170 | 100 | 95 | 80 | 70 |
| of mold release layer | | | | | | | | | |
| (%) | | | | | | | | | |
| Releasability with respect | A | A | A | B | B | A | A | A | A |
| to EMC | | | | | | | | | |
| Mold release layer | A | A | A | A | A | B | B | B | B |
| remaining | | | | | | | | | |

As shown in Table 2, in Examples 1 to 5, the mold release layer remaining on the SUS plate was not confirmed. On the other hand, in Comparative Examples 1 to 4, the mold release layer remaining on the SUS plate was confirmed.

### Example 6

A synthetic urethane resin 1 having a constituent unit (PO) having a propylene oxide skeleton, a constituent unit (EO) having an ethylene oxide skeleton, and a constituent unit (HDI) derived from hexamethylene diisocyanate in a molar ratio shown in Table 3 was prepared. The molar ratio of each constituent unit in the synthetic urethane resin 1 is a value calculated from the peak area ratio of ¹H NMR. Since the peak of ¹H NMR in each constituent unit partially overlapped with the peak of ¹H NMR derived from a solvent, another component, or the like, a peak that did not overlap as much as possible was selected, and the molar ratio of each constituent unit was calculated.

A composition for forming a mold release layer was prepared by mixing 100 parts by mass of the synthetic urethane resin 1 with a toluene solution having a solid content of 15% by mass prepared by adding 20 parts by mass of Coronate L (TOSOH CORPORATION, trade name) as a crosslinking agent to toluene. A biaxially stretched polyethylene terephthalate film (UNITIKA LTD.: S-38) subjected to a corona treatment and having an average thickness of 38 μm was used as a base material layer. Thereafter, the composition for forming a mold release layer was applied to one surface of the base material layer using a roll coater so that the average thickness after drying was 5 μm, and dried to form a mold release layer, thereby obtaining a mold release film.

### Example 7

A mold release film was prepared in the same manner as in Example 1, except that the average thickness of the mold release layer after drying was set to 10 μm.

### Example 8

A mold release film was prepared in the same manner as in Example 1, except that the average thickness of the mold release layer after drying was set to 25 μm.

### Example 9

A mold release film was prepared in the same manner as in Example 7, except that the crosslinking agent was set to 40 parts by mass with respect to 100 parts by mass of the urethane resin.

### Example 10

A mold release film was prepared in the same manner as in Example 9, except that the average thickness of the mold release layer after drying was set to 15 μm.

### Example 11

A synthetic urethane resin 2 having a constituent unit (PO) having a propylene oxide skeleton, a constituent unit (EO) having an ethylene oxide skeleton, and a constituent unit (HDI) derived from hexamethylene diisocyanate in a molar ratio shown in Table 3 was prepared. The molar ratio of each constituent unit in the synthetic urethane resin 2 is a value calculated from the peak area ratio of ¹H NMR. Since the peak of ¹H NMR in each constituent unit partially overlapped with the peak of ¹H NMR derived from a solvent, another component, or the like, a peak that did not overlap as much as possible was selected, and the molar ratio of each constituent unit was calculated.

A composition for forming a mold release layer was prepared by mixing 100 parts by mass of the synthetic urethane resin 2 with a toluene solution having a solid content of 15% by mass prepared by adding 10 parts by mass of Coronate L (TOSOH CORPORATION, trade name) as a crosslinking agent to toluene. A biaxially stretched polyethylene terephthalate film (UNITIKA LTD.: S-38) subjected to a corona treatment and having an average thickness of 38 μm was used as a base material layer. Thereafter, the composition for forming a mold release layer was applied to one surface of the base material layer using a roll coater so that the average thickness after drying was 15 μm, and dried to form a mold release layer, thereby obtaining a mold release film.

### Example 12

A mold release film was prepared in the same manner as in Example 11, except that the crosslinking agent was set to 20 parts by mass with respect to 100 parts by mass of the urethane resin.

### Example 13

A mold release film was prepared in the same manner as in Example 11, except that the average thickness of the mold release layer after drying was set to 25 μm.

For the mold release films of Examples 6 to 13, the elongation rate at break of the mold release layer, the releasability with respect to EMC, and the mold release layer remaining were evaluated in the same manner as in the mold release films of Examples 1 to 5. The results are shown in Table 4.

TABLE 3

| | Synthetic | Synthetic |
|---|---|---|
| | urethane | urethane |
| | resin 1 | resin 2 |
| PO | 55 | 45 |
| EO | 10 | 40 |
| HDI | 1 | 1 |
| Number average molecular weight Mn | 12,000 | 3,400 |
| Weight average molecular weight Mw | 190,000 | 89,000 |

TABLE 4

| | | Example 6 | Example 7 | Example 8 | Example 9 | Example 10 | Example 11 | Example 12 | Example 13 |
|---|---|---|---|---|---|---|---|---|---|
| Mold | Synthetic | 100 | 100 | 100 | 100 | 100 | | | |
| release | urethane | | | | | | | | |
| layer main | resin 1 | | | | | | | | |
| agent | Synthetic | | | | | | 100 | 100 | 100 |
| | urethane | | | | | | | | |
| | resin 2 | | | | | | | | |

| | | | | | | | | |
|---|---|---|---|---|---|---|---|---|
| Crosslinking agent (parts | 20 | 20 | 20 | 40 | 40 | 10 | 20 | 10 |
| by mass) | | | | | | | | |
| Average thickness of mold | 5 | 10 | 25 | 10 | 15 | 15 | 15 | 25 |
| release layer (μm) | | | | | | | | |
| Elongation rate at break of | 180≤ | 180≤ | 165 | 180≤ | 170 | 160 | 140 | 130 |
| mold release layer (%) | | | | | | | | |
| Releasability with respect | A | A | A | B | B | A | A | A |
| to EMC | | | | | | | | |
| Mold release layer | A | A | A | A | A | A | A | A |
| remaining | | | | | | | | |

As shown in Table 4, in Examples 6 to 13, the mold release layer remaining on the SUS plate was not confirmed.

The entire contents of the disclosures by Japanese Patent Application No. 2022-146410 filed on Sep. 14, 2022 are incorporated herein by reference.

All the literature, patent application, and technical standards cited herein are also herein incorporated to the same extent as provided for specifically and severally with respect to an individual literature, patent application, and technical standard to the effect that the same should be so incorporated by reference.

1. A mold release film comprising: a mold release layer; and a base material layer,
wherein an elongation rate at break of the mold release layer is 120% or more, and an average thickness of the mold release layer is 5 μm or more.

2. The mold release film according to claim 1, wherein the mold release layer contains a urethane resin.

3. A mold release film comprising: a mold release layer; and a base material layer,
wherein the mold release layer contains a urethane resin, and the urethane resin includes a constituent unit 1 having an alkylene oxide skeleton.

4. The mold release film according to claim 1, wherein the base material layer is a polyester film.

5. The mold release film according to claim 2, wherein the urethane resin includes a constituent unit 1 having an alkylene oxide skeleton.

6. The mold release film according to claim 3, wherein the constituent unit 1 includes at least one of a constituent unit 2 having an ethylene oxide skeleton or a constituent unit 3 having a propylene oxide skeleton.

7. The mold release film according to claim 3, wherein the urethane resin further includes a constituent unit 4 having each urethane bond at both ends of a divalent linking group, and a total content ratio of the constituent unit 2 and the constituent unit 3 is 50 mol % or more with respect to a total of the constituent unit 1 and the constituent unit 4.

8. The mold release film according to claim 3, wherein the constituent unit 1 includes the constituent unit 2 and the constituent unit 3, and a ratio of the constituent unit 2 and the constituent unit 3, i.e., the constituent unit 2: the constituent unit 3 is from 10:90 to 60:40.

9. The mold release film according to claim 2, wherein the urethane resin includes a constituent unit 4 having each urethane bond at both ends of a divalent linking group, and the divalent linking group is a hexamethylene group, a 2,2,4-trimethylhexamethylene group, a 2,4,4-trimethylhexamethylene group, a pentamethylene group, or a tetramethylene group.

10. The mold release film according to claim 1, wherein the mold release film is used in transfer molding or compression molding.

11. A method for manufacturing a semiconductor package, comprising performing transfer molding or compression molding using the mold release film according to claim 1.

12. The mold release film according to claim 3, wherein the base material layer is a polyester film.

13. The mold release film according to claim 5, wherein the constituent unit 1 includes at least one of a constituent unit 2 having an ethylene oxide skeleton or a constituent unit 3 having a propylene oxide skeleton.

14. The mold release film according to claim 5, wherein the urethane resin further includes a constituent unit 4 having each urethane bond at both ends of a divalent linking group, and a total content ratio of the constituent unit 2 and the constituent unit 3 is 50 mol % or more with respect to a total of the constituent unit 1 and the constituent unit 4.

15. The mold release film according to claim 6, wherein the urethane resin further includes a constituent unit 4 having each urethane bond at both ends of a divalent linking group, and a total content ratio of the constituent unit 2 and the constituent unit 3 is 50 mol % or more with respect to a total of the constituent unit 1 and the constituent unit 4.

16. The mold release film according to claim 5, wherein the constituent unit 1 includes the constituent unit 2 and the constituent unit 3, and a ratio of the constituent unit 2 and the constituent unit 3, i.e., the constituent unit 2:the constituent unit 3 is from 10:90 to 60:40.

17. The mold release film according to claim 6, wherein the constituent unit 1 includes the constituent unit 2 and the constituent unit 3, and a ratio of the constituent unit 2 and the constituent unit 3, i.e., the constituent unit 2:the constituent unit 3 is from 10:90 to 60:40.

18. The mold release film according to claim 7, wherein the constituent unit 1 includes the constituent unit 2 and the constituent unit 3, and a ratio of the constituent unit 2 and the constituent unit 3, i.e., the constituent unit 2:the constituent unit 3 is from 10:90 to 60:40.

19. The mold release film according to claim 3, wherein the urethane resin includes a constituent unit 4 having each urethane bond at both ends of a divalent linking group, and the divalent linking group is a hexamethylene group, a 2,2,4-trimethylhexamethylene group, a 2,4,4-trimethylhexamethylene group, a pentamethylene group, or a tetramethylene group.

20. The mold release film according to claim 5, wherein the urethane resin includes a constituent unit 4 having each urethane bond at both ends of a divalent linking group, and the divalent linking group is a hexamethylene group, a 2,2,4-trimethylhexamethylene group, a 2,4,4-trimethylhexamethylene group, a pentamethylene group, or a tetramethylene group.
